(19) United States
(12) Patent Application Publication
(10) Pub. No.: US 2026/0293246 A1
(43) Pub. Date: Sep. 24, 2026

(54) SOURCE/DRAIN STRUCTURE AND METHODS THEREOF

(71) Applicant: Taiwan Semiconductor Manufacturing Company, Ltd., Hsinchu (TW)

(72) Inventors: Kun-Chuan Lee, Hsinchu (TW); Tsung-Hsi Yang, Hsinchu County (TW); Yi-Fang Pai, Hsinchu City (TW)

(21) Appl. No.: 19/086,422

(22) Filed: Mar. 21, 2025

(51) Int. Cl. H10D 62/13; H10D 30/00; H10D 62/00; H10D 64/23

(52) U.S. Cl. CPC H10D 62/151; H10D 30/501; H10D 62/01; H10D 64/251

(57) ABSTRACT

Methods and structures for forming a source/drain feature having a V-shaped profile to effectively reduce source/drain contact resistance. In some embodiments, a semiconductor device includes a plurality of stacked nanostructures disposed over a substrate, a source/drain feature adjacent to the plurality of stacked nanostructures, and a source/drain contact feature disposed over the source/drain feature. In some embodiments, the source/drain feature has a substantially V-shaped profile along a top surface of the source/drain feature.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reducing OFF-state current, and reducing short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAAs are compatible with conventional complementary metal-oxide-semiconductor (CMOS) processes and their three-dimensional structure allows them to be aggressively scaled while maintaining gate control and mitigating SCEs. However, such advanced devices also present new challenges. Indeed, one of the most pressing existing challenges is the reduction of source/drain contact resistance. While various strategies have been proposed to address this issue, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 provides an exemplary semiconductor device including a source/drain feature with a V-shaped profile, in accordance with some embodiments;

FIG. 3 provides the exemplary semiconductor device of FIG. 2 with an exemplary overlay depicting a first layer ‘L1’ and second layer ‘L2’, in accordance with some embodiments;

FIG. 4 provides an exemplary semiconductor device including a source/drain feature with a V-shaped profile and a dopant species rich layer, in accordance with some embodiments;

FIG. 5 provides an exemplary semiconductor device including an etched back source/drain feature with a V-shaped profile and a dopant species rich layer, in accordance with some embodiments;

FIG. 6 provides an exemplary semiconductor device including an etched back source/drain feature with a V-shaped profile and a dopant species rich layer, in accordance with other embodiments;

FIG. 7 provides an exemplary semiconductor device including a source/drain feature with a V-shaped profile and curved profile regions, in accordance with some embodiments; and

FIG. 8 is a flow chart of a method of fabricating a semiconductor device having a source/drain feature with a V-shaped profile, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm. To be sure, in some embodiments, the terms such as “substantially equal”, “equal”, or “about” may alternatively be understood to mean within a different percentage or range of the recited value, not limited to +/−10%, where such a different percentage or range may be known by those skilled in the art and may be dependent on various process, material, and/or device conditions or features.

It is also noted that the present disclosure presents embodiments in the form of a source/drain feature which may be employed in any of a variety of device types. For example, embodiments of the present disclosure may be used to form source/drain features in multi-gate devices which may include a P-type metal-oxide-semiconductor device or an N-type metal-oxide-semiconductor multi-gate device. Specific examples may be presented and referred to herein as fin field-effect transistors (FinFETs), on account of their fin-like structure. FinFET devices may include fins extending from a substrate (or nanostructures extending from a substrate), where the fins are composed of a substantially uniform composition. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in various nanostructures such as nanosheet channel(s), nanowire channel(s), bar-shaped channel(s), and/or other suitable channel configurations. Presented herein are embodiments of devices that may have one or more nanostructured channel regions (e.g., nanowires/nanosheets) associated with a single, contiguous gate structure. GAA devices may include a plurality of stacked channel layers (e.g., a plurality of stacked nanosheets) that form the channels of a GAA transistor. One of ordinary skill would recognize that the teachings disclosed herein can apply to a single channel (e.g., single nanowire/nanosheet) or any number of channels. One of ordinary skill may recognize other examples of semiconductor devices that may benefit from aspects of the present disclosure. For example, in some cases, aspects of the present disclosure may be equally applicable to planar transistor devices, forksheet devices, complementary FET (CFET) devices, and the like. CFET devices include a first transistor of a first conductivity type (e.g., n-type or p-type) vertically stacked over a second transistor having an opposite conductivity type. In some examples, GAA transistors may be used to implement CFET devices. One of ordinary skill may recognize other embodiments of semiconductor devices that may benefit from aspects of the present disclosure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for forming a source/drain feature, such as an epitaxial source/drain feature, to effectively reduce source/drain contact resistance. Lowering source/drain contact resistance is crucial for boosting device performance, and an effective way to modulate source/drain contact resistance is by modulating a contact area between an epitaxial source/drain feature and an overlying contact metal layer. In some existing implementations, the contact area between the source/drain feature and the contact metal layer is defined by a source/drain recess process, which results in a substantially U-shaped profile disposed along a top surface of the source/drain feature. In contrast, embodiments of the present disclosure provide for an increased contact area between the source/drain feature and the contact metal layer by providing a substantially V-shaped profile disposed along the top surface of the source/drain feature. In various embodiments, the V-shaped profile of the source/drain feature may be formed by control of the epitaxial growth process used to form the source/drain feature. For example, in some cases, silicon precursors including silane (SiH₄) and dichlorosilane (SiH₂Cl₂) may be used during the epitaxial growth of the source/drain feature. In particular, and in various embodiments, by controlling the ratio of silane-to-dichlorosilane during the epitaxial growth process, the V-shaped profile of the source/drain feature may be formed. In some examples, the ratio of silane-to-dichlorosilane used for the epitaxial growth process is between about 0 (no silane) to about 0.4. Additional details of embodiments of the present disclosure are provided below, and additional benefits and/or other advantages will become apparent to those skilled in the art having benefit of the present disclosure.

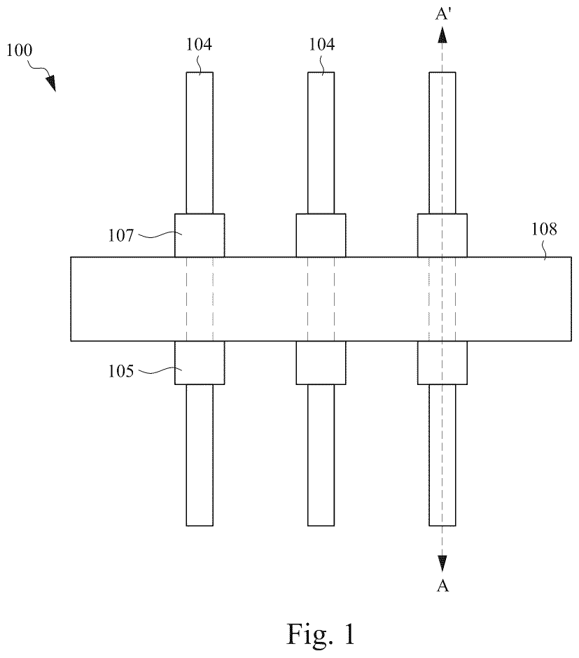

As discussed above, embodiments of the present disclosure may be applicable to various types of devices such as planar transistor devices, FinFET devices, GAA devices including a plurality of nanosheet channel layers, forksheet devices, CFET devices having a first transistor of a first conductivity type (e.g., n-type or p-type) vertically stacked over a second transistor having an opposite conductivity type, and others. However, for clarity of discussion, aspects of the disclosed embodiments will be discussed with reference to an exemplary multi-gate device, such as shown and described below. By way of example, FIG. 1 provides a simplified top-down layout view of a multi-gate device 100. While not limited thereto, for purposes of this discussion the multi-gate device 100 may include a GAA device. In various embodiments, the multi-gate device 100 may include a FinFET device or other type of multi-gate device. The multi-gate device 100 may include a plurality of fin elements 104 (each including a plurality of nanosheets) extending from a substrate, a gate structure 108 disposed over and around the fin elements 104, and source/drain regions 105, 107, where the source/drain regions 105, 107 are formed in, on, and/or surrounding the fins 104. A channel region of the multi-gate device 100, which may include a plurality of semiconductor channel layers provided by the plurality of nanosheets, is disposed within the fins 104, underlying the gate structure 108, along a plane substantially parallel to a plane defined by section AA′ of FIG. 1. In some embodiments, sidewall spacers may also be formed on sidewalls of the gate structure 108.

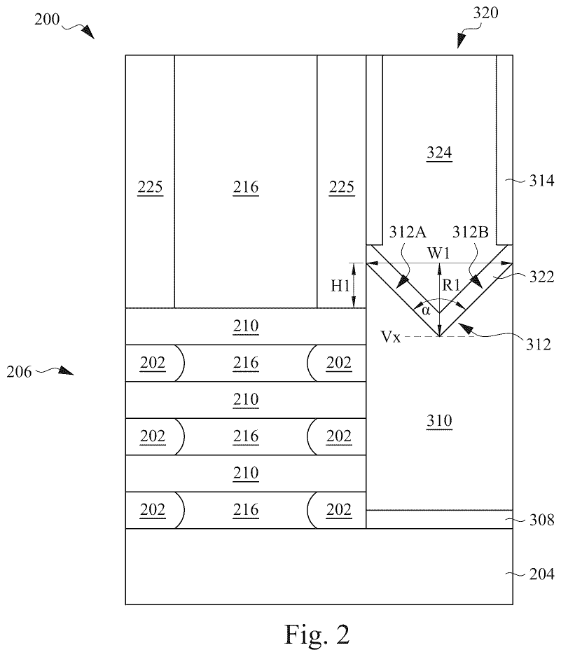

Referring now to FIG. 2, illustrated therein is an exemplary semiconductor device 200 including a source/drain feature with a V-shaped profile, in accordance with some embodiments of the present disclosure. In some embodiments, the semiconductor device 200 may include the multi-gate device 100, such as a GAA device. Thus, one or more aspects discussed above with reference to the multi-gate device 100 may also apply to the semiconductor device 200. In particular, FIG. 2 provides a cross-sectional view of the semiconductor device 200 along a plane substantially parallel to a plane defined by section AA′ of FIG. 1 (e.g., along the direction of a fin 206).

The device 200 may be formed on a substrate 204. In some embodiments, the substrate 204 may be a semiconductor substrate such as a silicon substrate. The substrate 204 may include various layers, including conductive or insulating layers formed on a semiconductor substrate. The substrate 204 may include various doping configurations depending on design requirements as is known in the art. The substrate 204 may also include other semiconductors such as germanium, silicon carbide (SiC), silicon germanium (SiGe), or diamond. Alternatively, the substrate 204 may include a compound semiconductor and/or an alloy semiconductor. Further, the substrate 204 may optionally include an epitaxial layer (epi-layer), may be strained for performance enhancement, may include a silicon-on-insulator (SOI) structure, and/or have other suitable enhancement features.

As shown in FIG. 2, the device 200 includes the fin 206 having a plurality of stacked epitaxial layers 210. In some cases, shallow trench isolation (STI) features may be formed to isolate the fin 206 from neighboring fins. In various embodiments, the epitaxial layers 210, or portions thereof, may form a channel region of a GAA transistor of the device 200. For example, the epitaxial layers 210 may be referred to as semiconductor channel layers that are used to form a channel region of a GAA transistor. The epitaxial layers 210, in some embodiments, may include silicon (Si). In various embodiments, the semiconductor channel layers (e.g., the layers 210 or portions thereof) may include various nanostructures such as nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the device 200 is illustrated as including three (3) layers of the epitaxial layer 210, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the device 200 (e.g., for the GAA transistor). In some embodiments, the number of epitaxial layers 210, and thus the number of semiconductor channel layers, is between 3 and 10.

In some cases, the epitaxial layers 210 (the semiconductor channel layers) may each have a thickness in a range of about 5-15 nm. In some embodiments, a spacing between each of the epitaxial layers 210 may be in a range of between about 5-15 nm. The spacing between the adjacent epitaxial layers 210 may be defined by a thickness of dummy layers (e.g., SiGe layers) that initially interpose the adjacent epitaxial layers 210, but which are later replaced by inner spacers 202 and portions of a gate structure 216, discussed in more detail below. As noted above, the epitaxial layers 210 may serve as channel region(s) for a subsequently-formed multi-gate device (e.g., a GAA transistor) and their thickness may be chosen based at least in part on device performance considerations. The spacing between adjacent channel region(s) for the subsequently-formed multi-gate device may also be chosen based at least in part on device performance considerations.

The device 200 further includes a gate structure 216 formed over the fin 206, over the stacked epitaxial layers 210, and interposing portions of adjacent epitaxial layers 210. In an embodiment, the gate structure 216 includes a high-K dielectric layer (HK)/metal gate (MG) structure. In various embodiments, the gate structure 216 may be formed using a replacement gate (gate-last) process whereby a dummy gate structure is formed and subsequently replaced by the HK/MG structure. In some cases, the gate structure 216 may instead be formed using a gate-first process. The portion of the fin 206 underlying the gate structure 216 may be referred to as the channel region of the device 200. The gate structure 216 may also define a source/drain region of the fin 206, for example, the regions of the fin 206 adjacent to and on opposing sides of the channel region. In various embodiments, the gate structure 216 forms the gate associated with the multi-channels provided by the plurality of semiconductor channel layers (the epitaxial layers 210).

In some embodiments, the gate structure 216 includes a dielectric layer and an electrode layer over the dielectric layer. The gate structure 216 may include an interfacial layer (IL) formed on surfaces of the epitaxial layers 210, a high-K dielectric layer disposed over the IL, and a metal layer that defines a metal gate disposed over the high-K dielectric layer. In various embodiments, the IL and the high-K dielectric layer may collectively define a gate dielectric of the gate structure 216 for the device 200. In some embodiments, the gate dielectric has a total thickness of about 1-5 nm. High-K gate dielectrics, as used and described herein, include dielectric materials having a high dielectric constant, for example, greater than that of thermal silicon oxide (~3.9).

In some embodiments, the IL of the gate structure 216 may include a dielectric material such as silicon oxide (SiO₂), HfSiO, or silicon oxynitride (SiON). In some examples, the high-K dielectric layer of the gate structure 216 may include hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), combinations thereof, or other suitable material.

In some examples, the metal gate of the gate structure 216 may include a metal, metal alloy, or metal silicide. In some embodiments, the metal gate of the gate structure 216 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal gate of the gate structure 216 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. Further, the metal gate of the gate structure 216 may be formed separately for N-type and P-type transistors which may use different metal layers. In addition, the metal gate of the gate structure 216 may provide an N-type or P-type work function, may serve as a transistor (e.g., GAA transistor) gate electrode, and in at least some embodiments, the metal gate of the gate structure 216 may include a polysilicon layer. Also, the gate structure 216 includes portions that interpose each of the epitaxial layers 210, which each provide semiconductor channel layers for the GAA transistor.

In some embodiments, the device 200 further includes spacer layers 225 disposed on sidewalls of the gate structure 216. In some cases, the spacer layers 225 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In some embodiments, the spacer layers 225 may include main spacer layers, liner layers, and the like, as well as other spacer layers.

In some embodiments, and prior to replacing the dummy gate structure with the gate structure 216, a source/drain etch process may be performed to remove portions of the epitaxial layer 210, as well as portions of the dummy layers (e.g., SiGe layers) that initially interpose the adjacent epitaxial layers 210, in source/drain regions of the device 200 (e.g., adjacent to and on either side of the gate structure 216) to form trenches which expose underlying portions of the substrate 204. The source/drain etch process also serves to expose lateral surfaces of the epitaxial layer 210 and the dummy layers that interpose the adjacent epitaxial layers 210 prior to formation of the high-K/metal gate structure 216.

After the source/drain etch process, the dummy layers (e.g., SiGe layers) that interpose the adjacent epitaxial layers 210 are etched along their exposed lateral ends to form recesses within which the inner spacers 202 are formed. In some embodiments, the inner spacers 202 may include amorphous silicon. In some examples, the inner spacers 202 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In various examples, the inner spacers 202 may extend beneath the spacer layers 225 (formed on sidewalls of the gate structure 216) while being disposed adjacent to subsequently formed source/drain features, described in more detail below. In some cases, the inner spacers 202 may extend at least partially beneath the gate structure 216.

In various embodiments, the gate structure 216 is formed after formation of the inner spacers 202 and after formation of a source/drain feature 310, for example, by using a replacement gate process to remove the dummy gate structure and remaining portions of the dummy layers (e.g., SiGe layers) and replacing them with the gate structure 216. Thus, as shown, the inner spacers 202 may be formed such that they are in contact with opposing ends of portions of the gate structure 216 disposed between adjacent epitaxial layers 210. The inner spacers 202 are also in contact with respective top and bottom surfaces of lateral ends of adjacent epitaxial layers 210. In some embodiments, the inner spacers 202 have a convex sidewall profile in contact with the opposing ends of the portions of the gate structure 216 which have a complementary concave sidewall profile, as shown. In some cases, the convex/concave sidewall profiles are defined by the etching of the lateral ends of the dummy layers to form the recesses within which the inner spacers 202 are formed.

After formation of the inner spacers 202, an interposing layer, such as an isolation layer 308 is formed within the trenches (e.g., formed by the source/drain etch process) of the device 200 and over the exposed portions of the substrate 204. In some cases, the isolation layer 308 may include a dielectric material such as silicon oxide, silicon nitride, silicon carbide, silicon oxynitride, SiCN, silicon oxycarbide, SiOCN, aluminum oxide, hafnium oxide, a low-K material (e.g., with a dielectric constant ‘k’<7), and/or combinations thereof. In some cases, the isolation layer 308 has a thickness of between about 1-5 nm. In some embodiments, the interposing layer may additionally or alternatively include an undoped silicon (Si) layer or an undoped silicon germanium (SiGe) layer. For example, in some embodiments, the interposing layer may include a multi-layer structure which includes an undoped Si layer (or undoped SiGe layer) and the isolation layer 308, where the isolation layer 308 is disposed on the undoped Si layer (or undoped SiGe layer). In some embodiments, the undoped Si layer (or undoped SiGe layer) has a bottom surface that is lower than a bottom surface of the bottommost inner spacer 202. The isolation layer 308 may be equally referred to as a flexible bottom isolation (FBI) layer, in some cases. In various embodiments, the isolation layer 308 may serve to reduce leakage current along a bottom portion of a source/drain feature 310. In some examples, the source/drain features 310, in turn, are formed in source/drain regions adjacent to and on either side of the gate structure 216 of the device 200. For example, the source/drain features 310 may be formed over the isolation layer 308 and in contact with the adjacent inner spacers 202 and the semiconductor channel layers (the epitaxial layers 310) of the device 200.

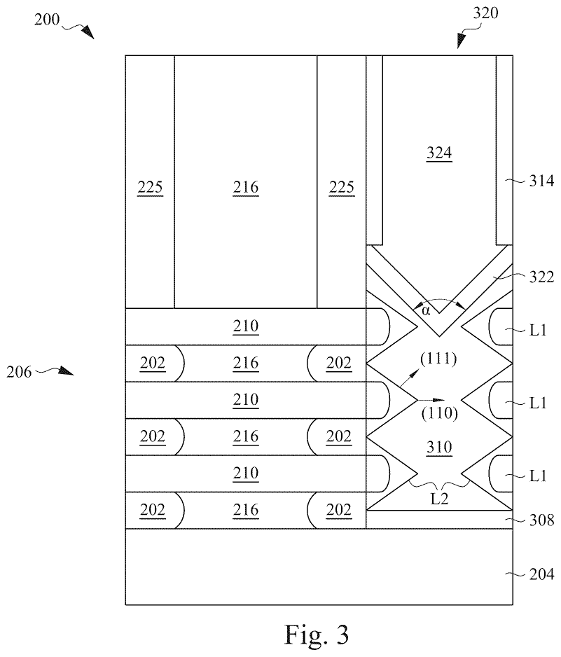

As shown in FIG. 2, the source/drain feature 310 has a substantially V-shaped profile 312 along a top surface of the source/drain feature 310. In some embodiments, the source/drain feature 310 is formed by epitaxially growing one or more semiconductor material layers in the source/drain regions. In general, the one or more semiconductor material layers grown to form the source/drain feature 310 may include Ge, Si, GaAs, AlGaAs, SiGe, GaAsP, SiP, SiB, SiGeBx, SiAs, SiPAsx, SiC, SiCP, or other suitable material. Source/drain features (e.g., such as the source/drain feature 310) may be formed by one or more epitaxial (epi) processes, and in some cases, may thus include multiple epitaxially grown layers. For example, as discussed in more detail with reference to FIG. 3, a first layer ‘L1’ may be formed on lateral ends of the epitaxial layers 210 (the channel layers), and a second layer ‘L2’ may be formed over the first layer ‘L1’ and thus provide most of, or form the bulk of, the source/drain feature 310. In some embodiments, the source/drain features (e.g., such as the source/drain feature 310) may be in-situ doped during the epi growth process. By way of example, and in some embodiments, P-type source/drain features may be formed within a P-type device region and may include SiGe or a boron-doped epitaxial layer such as SiB or SiGeBx. Likewise, and in some embodiments, N-type source/drain features may be formed within an N-type device region and may include SiP or an arsenic-doped epitaxial layer such as SiAs or SiPAsx. In some embodiments, the source/drain feature 310 is not in-situ doped, and instead an ion implantation process is performed to dope the source/drain feature 310.

In addition, and in some cases, silane (SiH₄), dichlorosilane (SiH₂Cl₂), or a combination thereof may be used for the epitaxial layer growth of the source/drain feature 310. In particular, and in various embodiments, by controlling the ratio of silane-to-dichlorosilane during the epitaxial growth of the source/drain feature 310, the V-shaped profile 312 may be formed. In some examples, the ratio of silane-to-dichlorosilane used during the epitaxial growth of the source/drain feature 310 is between about 0 (no silane) to about 0.4. To provide the desired ratio of silane-to-dichlorosilane, during the epitaxial growth process and in various embodiments, a flow rate of each of the silane precursor and the dichlorosilane precursor should be carefully controlled. In various embodiments, the flow rate of the respective ones of the silane precursor and the dichlorosilane precursor may depend on which layer of the multiple epitaxially grown layers of the source/drain feature 310 is being formed (e.g., such as the first layer ‘L1’ or the second layer ‘L2’). Generally, whether forming the first layer ‘L1’ or the second layer ‘L2’, the flow rate of the silane precursor may be in a range between about 0-150 standard cubic centimeters per minute (sccm), and the flow rate of the dichlorosilane precursor may be in a range between about 100-900 sccm. However, in some embodiments and in order to provide the desired V-shaped profile 312, an amount of dichlorosilane may be higher during growth of the second layer ‘L2’ as compared to during growth of the first layer ‘L1’.

Carrier gases such as hydrogen (H₂), nitrogen (N₂), argon (Ar), and helium (He) may also be used during the epitaxial growth of the source/drain feature 310, and the flow rate of the respective ones of the carrier gases may depend on which layer of the multiple epitaxially grown layers of the source/drain feature 310 is being formed (e.g., such as the first layer ‘L1’ or the second layer ‘L2’). As an example, when forming the first layer ‘L1’, the flow rate of an H₂ carrier gas may be in a range between about 0-20 standard liters per minute (slm), and the flow rate of an N₂ carrier gas may be in a range between about 0-20 slm. As another example, when forming the second layer ‘L2’, the flow rate of an H₂ carrier gas may be in a range between about 0-20 slm, and the flow rate of an N₂ carrier gas may be in a range between about 0-15 slm.

Further, the pressure and temperature used during epitaxial growth of the source/drain feature 310 may depend on which layer of multiple epitaxially grown layers of the source/drain feature 310 is being formed (e.g., such as the first layer ‘L1’ or the second layer ‘L2’). In some embodiments, when forming the first layer ‘L1’, the epitaxial growth of the source/drain feature 310 may be performed at a temperature of between about 650 C-750 C and at a pressure of between about 50 Torr to about 500 Torr. In other embodiments, when forming the second layer ‘L2’, the epitaxial growth of the source/drain feature 310 may be performed at a temperature of between about 600 C-780 C and at a pressure of between about 50 Torr to about 500 Torr.

As discussed, the source/drain feature 310 may be formed using multiple epitaxially grown layers (e.g., such as the first layer ‘L1’ or the second layer ‘L2’). In some cases, such multiple epitaxially grown layers may have different material compositions, different dopant species and dopant concentrations, and different volumes. For example, in some embodiments, the first layer ‘L1’ of the source/drain feature 310 may include a lower-doped layer (e.g., such as lightly boron-doped SiGe for P-type source/drain features or a lightly arsenic-doped SiP for N-type source/drain features) to prevent out-diffusion and/or suppress leakage current, and the second layer ‘L2’ of the source/drain feature 310 may include a higher-doped layer (e.g., such as heavily boron-doped SiGe for P-type source/drain features or heavily arsenic-doped SiP for N-type source/drain features) to reduce source/drain contact resistance. Generally, and in various embodiments, the multiple epitaxially grown layers of the source/drain feature 310 may be doped with a variety of dopant species and may have a variety of dopant concentrations, for example, depending on the device type (N-type or P-type) and device and process design specifications.

More generally, and in various embodiments, one or more of the multiple epitaxially grown layers (e.g., such as the first layer ‘L1’ or the second layer ‘L2’) of the source/drain feature 310 may be doped with boron (B), phosphorous (P), arsenic (As), germanium (Ge), carbon (C), antimony (Sb). In some embodiments, doping with arsenic may provide an As dopant concentration in a range between about 1×10¹⁹ cm⁻³-4×10²¹ cm⁻³. In some embodiments, doping with carbon may provide a C dopant concentration in a range between about 1×10¹⁹ cm⁻³-1×10²¹ cm⁻³. In some embodiments, doping with antimony may provide an Sb dopant concentration in a range between about 1×10¹⁹ cm⁻³-1×10²¹ cm⁻³. In some embodiments, doping with germanium may provide a Ge concentration of the respective epitaxially grown layer in a range between about 0% Ge-50% Ge. In some embodiments, doping with phosphorous may provide a P dopant concentration in a range between about 1×10¹⁹ cm⁻³-4×10²¹ cm⁻³. In some embodiments, doping with boron may provide a B dopant concentration in a range between about 1×10¹⁹ cm⁻³-4×10²¹ cm⁻³.

At least some of the dopant precursors that may be used to dope the source/drain feature 310, in various embodiments, include phosphine (PH₃), arsine (AsH₃), stibine (SbH₃), mono-methylsilane (MMS), germane (GeH₄), digermane (Ge₂H₆), diborane (B₂H₆), or methane (CH₄), among others. In various embodiments, the flow rate of the respective ones of the dopant precursors may depend on which layer of multiple epitaxially grown layers of the source/drain feature 310 is being formed (e.g., such as the first layer ‘L1’ or the second layer ‘L2’). Generally, and in some embodiments, a flow rate of the dopant precursor may be less than or equal to about 500 sccm. More particularly, and by way of example, when doping the first layer ‘L1’, a flow rate of phosphine (PH₃) may be in a range between about 30-270 sccm, a flow rate of arsine (AsH₃) may be in a range between about 30-270 sccm, a flow rate of stibine (SbH₃) may be in a range between about 30-360 sccm, and a flow rate of mono-methylsilane (MMS) may be in a range between about 0-150 sccm. As another example, when doping the second layer ‘L2’, a flow rate of phosphine (PH₃) may be in a range between about 0-500 sccm, a flow rate of arsine (AsH₃) may be in a range between about 0-270 sccm, a flow rate of stibine (SbH₃) may be in a range between about 0-360 sccm, a flow rate of mono-methylsilane (MMS) may be in a range between about 0-150 sccm, and a flow rate of germane (GeH₄) may be in a range between about 0-150 sccm.

In some embodiments, the V-shaped profile 312 forms an angle alpha (α) defined between opposing surfaces 312A, 312B of the V-shaped profile 312 disposed along a top surface of the source/drain feature 310. In some examples, the angle alpha (α) may be in a range between about 60 degrees and 95 degrees. As noted above, the V-shaped profile 312 may be formed by controlling the ratio of silane-to-dichlorosilane during the epitaxial growth of the source/drain feature 310 (including during the epitaxial growth of the first layer ‘L1’ and the second layer ‘L2’), and the ratio of silane-to-dichlorosilane used during the epitaxial growth of the source/drain feature 310 is between about 0 (no silane) to about 0.4. In particular, and in some embodiments, when the ratio of silane-to-dichlorosilane is smaller (e.g., closer to 0), the angle alpha (α) may also be smaller (e.g., closer to 60 degrees). Similarly, when the ratio of silane-to-dichlorosilane is larger (e.g., closer to 0.4), the angle alpha (α) may also be larger (e.g., closer to 95 degrees). Stated another way, the larger the ratio of silane-to-dichlorosilane during epitaxial growth, the larger the angle alpha (α) will be.

As also shown in FIG. 2, the source/drain feature 310 has a width W1. In some embodiments, the width W1 may be in a range between about 8 nm-25 nm. The V-shaped profile 312 may, in various cases, span an entirety of the width W1 of the source/drain feature 310. Thus, in some embodiments, the V-shaped profile 312 may also have the width W1 in the range between about 8 nm-25 nm. To be sure, in some case, the width of the V-shaped profile 312 may be less than the width W1 of the source/drain feature 310. The source/drain feature 310 further has a height H1, defined as a distance between a first plane defined by a top surface of the topmost epitaxial layer 210 and a second plane (parallel to the first plane) level with a topmost portion of the source/drain feature 310. For purposes of this disclosure, it will be understood that the topmost portion of the source/drain feature 310 corresponds to the two highest points of the V-shaped profile 312 on opposite (left and right) sides of the source/drain feature 310. In some embodiments, the height H1 may be in a range between about 0 nm-15 nm. When the height H1 is equal to 0 nm, the top surface of the topmost epitaxial layer 210 may be level with the topmost portion of the source/drain feature 310. In addition, a recess R1 of the V-shaped profile 312 of the source/drain feature 310 is defined as a distance between a vertex of the V-shaped profile 312 and the plane level with the topmost portion of the source/drain feature 310. In some embodiments, the recess R1 may be in a range between about 8 nm-30 nm. With respect to the example of FIG. 2, it is also noted that while the topmost portion of the source/drain feature 310 may extend above a plane defined by the top surface of the topmost epitaxial layer 210, a plane Vx that is level with the vertex of the V-shaped profile 312 may be disposed below the plane defined by the top surface of the topmost epitaxial layer 210. Additionally, in some cases and still with respect to the example of FIG. 2, the plane Vx may be disposed below a plane defined by a bottom surface of the topmost epitaxial layer 210. The various parameters described above (e.g., the width W1, the height H1, the recess R1, and the angle alpha) may be modulated by adjustment of one or more of the process conditions used for epitaxial growth of the source/drain feature 310.

After forming the source/drain feature 310, and in some embodiments, a dielectric layer 314 may be formed over the device 200, including over the source/drain feature 310. As shown in FIG. 2 and FIG. 3, for example, a bottom surface of the dielectric layer 314 may be higher than a bottom surface of the spacer layers 225. In some examples, the dielectric layer 314 may include a silicon nitride layer, silicon oxide layer, a silicon oxynitride layer, and/or other materials known in the art. After forming the dielectric layer 314, an etching process may be performed to pattern the dielectric layer 314 to form a contact opening in the region over the source/drain feature 310, where the contact opening exposes the V-shaped profile 312 of the source/drain feature 310. In some embodiments, the etching process may include a dry etching process, where portions of the dielectric layer 314 remain on sidewalls of the contact opening.

After formation of the contact opening, a source/drain contact feature 320 may be formed within the contact opening. In some embodiments, the source/drain contact 322 may include a silicide layer 322 in contact with the V-shaped profile 312 of the source/drain feature 310, and a contact metal layer 324 formed over the silicide layer 322. The silicide layer 322 and the contact metal layer 324 thus provide a low-resistance contact to the source/drain feature 310 of the device 200. In particular, and in contrast to at least some existing implementations, the V-shaped profile 312 provides an increased contact area between the source/drain feature 310 and the source/drain contact feature 320, thereby lowering the source/drain contact resistance and boosting performance of the device 200. It is also noted that, in various examples, an electrical conductivity of the silicide layer 322 may be greater than an electrical conductivity of the source/drain feature 310. In some embodiments, the silicide layer 322 may include TiSi, NiSi, and/or other suitable material. In some embodiments, the silicide layer 322 may also include a plurality of layers of the same or different material(s). In some examples, the silicide layer 322 may include the same or different material(s) for each of an N-type and a P-type device. In some embodiments, the silicide layer 322 may include a dual silicide process and structure, where a first material is used for an N-type device, and a second material is used for a P-type device. For instance, in some cases, the silicide layer 322 may include TiSi, Yb-doped TiSi, Zn-doped TiSi, and/or Yb/Zn-doped TiSi for an N-type device. In addition, and in some embodiments, the silicide layer 322 may include NiSi, Pt-doped NiSi, or TiSi for a P-type device

In some embodiments, the contact metal layer 324 may include tungsten, cobalt, or other appropriate metal layer. More generally, and in various embodiments, the contact metal layer 324 may include Ti, W, Co, Cu, Al, Mo, MoW, W, TiN, TaN, WN, silicides, combinations thereof, or other suitable conductive material. Thus, in some cases, the contact metal layer 324 may include a plurality of layers. It is also noted that, in various examples, an electrical conductivity of the contact metal layer 324 may be greater than an electrical conductivity of the source/drain feature 310 and greater than an electrical conductivity of the silicide layer 322. After formation of the contact metal layer 324, and in some embodiments, an ILD layer may be deposited over the device 200 and patterned (e.g., by a suitable combination of lithographic patterning and wet and/or dry etching), to form an opening that exposes the contact metal layer 324 and within which a VIA metal layer is deposited. In some embodiments, the VIA metal layer includes Ti, W, Co, Cu, Al, Mo, MoW, W, TiN, TaN, WN, silicides, combinations thereof, or other suitable conductive material. The VIA metal layer may further provide an electrical connection to a layer of a multi-level interconnect network.

With reference to FIG. 3, illustrated therein is the device 200 of FIG. 2 with an exemplary overlay depicting the first layer ‘L1’ and the second layer ‘L2’, or portions thereof, discussed above. In various embodiments, the first layer ‘L1’ and the second layer ‘L2’ collectively form the source/drain feature 310. To provide a better understanding of the mechanism by which the V-shaped profile 312 is formed, the overlaid depictions of the first layer ‘L1’ and the second layer ‘L2’, as shown in FIG. 3, illustrate the first layer ‘L1’ after completion of epitaxial growth of the first layer ‘L1’ and illustrate the second layer ‘L2’ during epitaxial growth of the second layer ‘L2’. In the example shown, the first layer ‘L1’ may be formed on lateral ends of the epitaxial layers 210 (the channel layers). While some dichlorosilane may be used in some embodiments, silane may be primarily used to form the layer ‘L1’ and silane has a higher nucleation rate on silicon (on the epitaxial layers 210) than on the inner spacers 202, leading to the discontinuous portions of the first layer ‘L1’ being only formed on the lateral ends of the epitaxial layers 210, as shown. To be sure, in some embodiments, the first layer ‘L1’ may include a continuous layer ‘L1’ along the sides of the source/drain feature 310. As shown, the second layer ‘L2’ is then formed over the first layer ‘L1’, and during growth of the second layer ‘L2’, the amount of dichlorosilane may be greater than that used to form the first layer ‘L1’. In particular, and in some embodiments, the ratio of silane-to-dichlorosilane during growth of at least the second layer ‘L2’ is between about 0 (no silane) to about 0.4. As previously discussed, when the ratio of silane-to-dichlorosilane is smaller (e.g., closer to 0), the angle alpha (α) may also be smaller (e.g., closer to 60 degrees), and when the ratio of silane-to-dichlorosilane is larger (e.g., closer to 0.4), the angle alpha (α) may also be larger (e.g., closer to 95 degrees). Stated another way, the larger the ratio of silane-to-dichlorosilane during epitaxial growth of at least the second layer ‘L2’, the larger the angle alpha (α) will be. By maintaining the ratio of silane-to-dichlorosilane during growth of at least the second layer ‘L2’ to between about 0 (no silane) and about 0.4, growth of the second layer ‘L2’ proceeds preferentially along the (110) crystal face as compared to the (111) crystal face, as shown, to form the desired V-shaped profile 312. If the ratio of silane-to-dichlorosilane is increased above 0.4, meaning there is an increased amount of silane, the V-shaped profile 312 may not be achieved. While the ratio of silane-to-dichlorosilane during growth of the second layer ‘L2’ is critical for at least the reasons discussed above, it is noted that in various embodiments, the ratio of silane-to-dichlorosilane during growth of the first layer ‘L1’ is not a key factor and may be generally chosen according to process and/or design preferences. In addition, in some embodiments, the first layer ‘L1’ may be omitted and the second layer ‘L2’ alone may provide the source/drain feature 310. In such an embodiment where the first layer ‘L1’ is omitted, the second layer ‘L2’ may be initially formed on the lateral ends of the epitaxial layers 210, and by maintaining the ratio of silane-to-dichlorosilane during growth of the second layer ‘L2’ to between about 0 (no silane) and about 0.4, growth of the second layer ‘L2’ proceeds preferentially along the (110) crystal face as compared to the (111) crystal face, as discussed above, to form the desired V-shaped profile 312. FIG. 3 also illustrates the first layer ‘L1’ and the second layer ‘L2’ on both sides of the source/drain feature 310. It will be understood that epitaxial growth occurs from both sides of the source/drain feature 310, such that portions of the second layer ‘L2’ growing from each of the opposite sides of the source/drain feature 310 will eventually merge to complete formation of the source/drain feature 310 and to complete formation of the V-shaped profile 312.

As noted above, there may be differences in processing conditions depending on whether the first layer ‘L1’ or the second layer ‘L2’ is being formed. For instance, whether forming the first layer ‘L1’ or the second layer ‘L2’, the flow rate of the silane precursor may be in a range between about 0-150 sccm, and the flow rate of the dichlorosilane precursor may be in a range between about 100-900 sccm. In embodiments where the silane flow rate is equal to 0 sccm, the respective layer ‘L1’ or ‘L2’ may be formed with only one silicon precursor (dichlorosilane). Alternatively, in embodiments where the silane flow rate is not equal to 0 sccm, then the respective layer ‘L1’ or ‘L2’ may be formed with a combination of silicon precursors (silane and dichlorosilane). Also, in order to provide the desired V-shaped profile 312, the amount (e.g., flow rate) of dichlorosilane may be higher during growth of the second layer ‘L2’ as compared to during growth of the first layer ‘L1’. Further, when forming the first layer ‘L1’, the flow rate of an H₂ carrier gas may be in a range between about 0-20 slm, and the flow rate of an N₂ carrier gas may be in a range between about 0-20 slm. In addition, when forming the second layer ‘L2’, the flow rate of an H₂ carrier gas may be in a range between about 0-20 slm, and the flow rate of an N₂ carrier gas may be in a range between about 0-15 slm. Thus, generally and in various embodiments, a single carrier gas or combination of carrier gases may be used. Also, when forming the first layer ‘L1’, the epitaxial growth of the source/drain feature 310 may be performed at a temperature of between about 650 C-750 C and at a pressure of between about 50 Torr to about 500 Torr. In contrast, when forming the second layer ‘L2’, the epitaxial growth of the source/drain feature 310 may be performed at a temperature of between about 600 C-780 C and at a pressure of between about 50 Torr to about 500 Torr. Furthermore, depending on the device type (e.g., N-type or P-type), the source/drain feature 310 may be doped with one or more N-type and/or P-type dopants, as previously discussed. Exemplary dopant species, dopant precursors, and dopant precursor flow rates with respect to the first layer ‘L1’ and the second layer ‘L2’of the source/drain feature 310 are as discussed above.

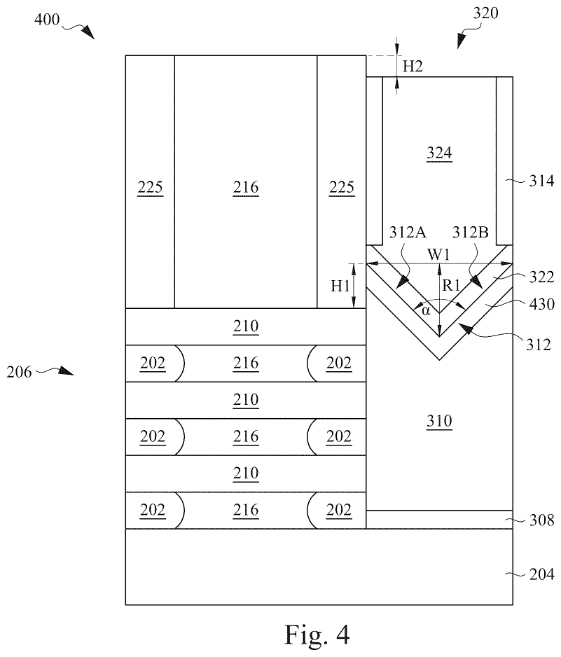

Referring to FIG. 4, illustrated therein is an exemplary semiconductor device 400 including a source/drain feature with a V-shaped profile, in accordance with some embodiments of the present disclosure. The device 400 is similar to the device 200 and includes many of the same features (identified by like reference numbers) as discussed above, thus for the sake of clarity only those features that are different in the device 400 are highlighted and discussed. As one example, and in some embodiments, the device 400 includes a dopant species rich layer 430 that is formed within a top portion of, and is thus part of, the source/drain feature 310. As shown, the dopant species rich layer 430 may be formed along the V-shaped profile 312 of the source/drain feature 310. Thus, in some examples, the silicide layer 322 may be formed in contact with the dopant species rich layer 430 of the source/drain feature 310. In some cases, the dopant species rich layer 430 may include one or more of the dopant species used to dope the source/drain feature 310 such as boron (B), phosphorous (P), arsenic (As), germanium (Ge), carbon (C), or antimony (Sb), depending on whether the source/drain feature 310 is for an N-type device or a P-type device. Further, in some embodiments, the dopant concentration of the dopant species rich layer 430 may be greater than the dopant concentration of the portion of the source/drain feature 310 disposed beneath the dopant species rich layer 430. In some embodiments, the dopant species rich layer 430 may be formed unintentionally as a by-product of device processing. To be sure, in some cases, the dopant species rich layer 430 may be intentionally formed. Whether formed intentionally or not, the dopant species rich layer 430 may provide for reduced contact resistance to the silicide layer 322, in some embodiments. In another example shown in the device 400, and in some embodiments, there may be an offset height H2 between a first plane defined by top surfaces of the spacer layers 225 and the gate structure 216 and a second plane defined by a top surface of the source/drain contact feature 320 (or the top surface of the contact metal layer 324). In some embodiments, the top surface of the source/drain contact feature 320 may also be coplanar with a top surface of the dielectric layer 314 disposed on opposite sides of the contact metal layer 324. In contrast and with reference to the device 200, discussed above, the top surfaces of the spacer layers 225, the gate structure 216, the contact metal layer 324 of the source/drain contact feature 320, and the dielectric layer 314 may be substantially coplanar. In some cases, the source/drain contact feature 320 of the device 400 has a smaller total height as compared to the source/drain contact feature 320 of the device 200, resulting in the offset height H2.

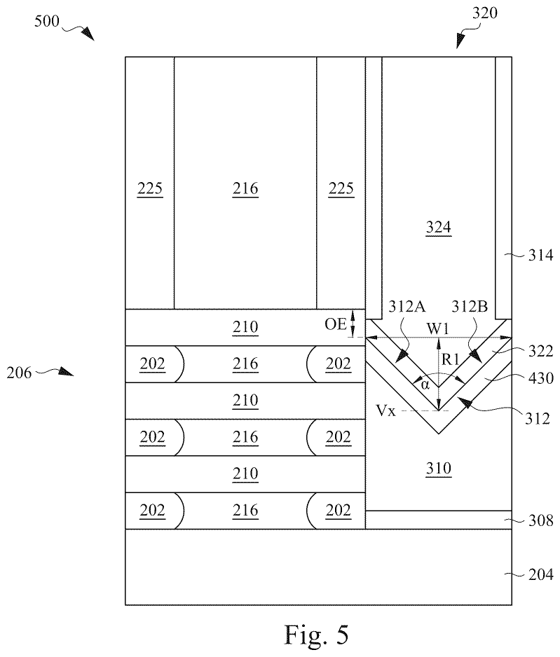

Referring to FIG. 5, illustrated therein is an exemplary semiconductor device 500 including a source/drain feature with a V-shaped profile, in accordance with some embodiments of the present disclosure. The device 500 is similar to the devices 200, 400 and includes many of the same features (identified by like reference numbers) as discussed above, thus for the sake of clarity only those features that are different in the device 500 are highlighted and discussed. In some embodiments, and with reference to the device 500, after forming the source/drain feature 310 and prior to forming the silicide layer 322, the source/drain feature 310 may be etched back to reduce a total height of the source/drain feature 310. As shown, and as a result of the etch back process, a topmost portion of the source/drain feature 310 may be disposed below a top surface of the topmost epitaxial layer 210. The distance by which the topmost portion of the source/drain feature 310 is disposed below the top surface of the topmost epitaxial layer 210 is referred to as an over etch height (notated as OE in FIG. 5).

In various embodiments, the etch back of the source/drain feature 310 may be performed using a dry etch, a wet etch, or a combination thereof. In some examples, hydrogen chloride (HCl) gas or chlorine (Cl₂) gas may be used to perform the etch back process of the source/drain feature 310. In some embodiments, when using HCl gas, the flow rate of the HCl gas may be in a range between about 30-600 sccm or in a range between about 0-600 sccm. In some cases, when using Cl₂ gas, the flow rate of the Cl₂ gas may be in a range between about 10-300 sccm. Further, it is noted that the shape of the V-shaped profile 312 is not substantially impacted by the etch back process. Stated another way, the V-shaped profile 312 may have a profile shape that is substantially the same before and after the etch back process. In some embodiments, the over etch height OE may be in a range between about 0 nm-10 nm. When the over etch height OE is equal to 0 nm, the top surface of the topmost epitaxial layer 210 may be level with the topmost portion of the source/drain feature 310. In some embodiments, such as shown in the example of the device 500, the over etch height OE may be substantially equal to a thickness of the topmost epitaxial layer 210 such that the topmost portion of the source/drain feature 310 is substantially level with a bottom surface of the topmost epitaxial layer 210. More generally, in various embodiments, the over etch height OE may be less than a sum of the thickness of the topmost epitaxial layer 210 and the thickness of the topmost inner spacer 202. As a result, the topmost portion of the source/drain feature 310 remains disposed above a top surface of the middle epitaxial layer 210. In some cases, the topmost portion of the source/drain feature 310 may be disposed below the bottom surface of the topmost epitaxial layer 210 and above the top surface of the middle epitaxial layer 210. In addition, with respect to the vertex of the V-shaped profile 312 in the example of FIG. 5, the plane Vx may be disposed below a plane defined by a top surface of the middle epitaxial layer 210. Further, in some cases and still with respect to the example of FIG. 5, the plane Vx may be disposed below a plane defined by a bottom surface of the middle epitaxial layer 210. In some embodiments, the top surfaces of the spacer layers 225, the gate structure 216, the contact metal layer 324 of the source/drain contact feature 320, and the dielectric layer 314 may be substantially coplanar, as shown in the device 500 and similar to the device 200, discussed above. In some alternative embodiments, there may be an offset height between a first plane defined by top surfaces of the spacer layers 225 and the gate structure 216 and a second plane defined by a top surface of the source/drain contact feature 320 (or the top surface of the contact metal layer 324), such as in the example of the device 400, discussed above.

In various embodiments, by performing the etch back process and lowering the topmost portion of the source/drain feature 310 by the over etch height OE, the contribution of the topmost epitaxial layer 210 to current flow of the device 500 can be reduced or eliminated, thereby providing a mechanism for modulating device performance. For example, if the over etch height OE less than or equal to the thickness of the topmost epitaxial layer 210, then the current flow between the source and drain of the device 500 will flow primarily through the middle and bottommost epitaxial layers 210, with a proportionally smaller current flowing through the topmost epitaxial layer 210. In another example, if the over etch height OE greater than the thickness of the topmost epitaxial layer 210, but less than the sum of the thickness of the topmost epitaxial layer 210 and the thickness of the topmost inner spacer 202, then the current flow between the source and drain of the device 500 will flow only through the middle and bottommost epitaxial layers 210, with substantially no current flowing through the topmost epitaxial layer 210.

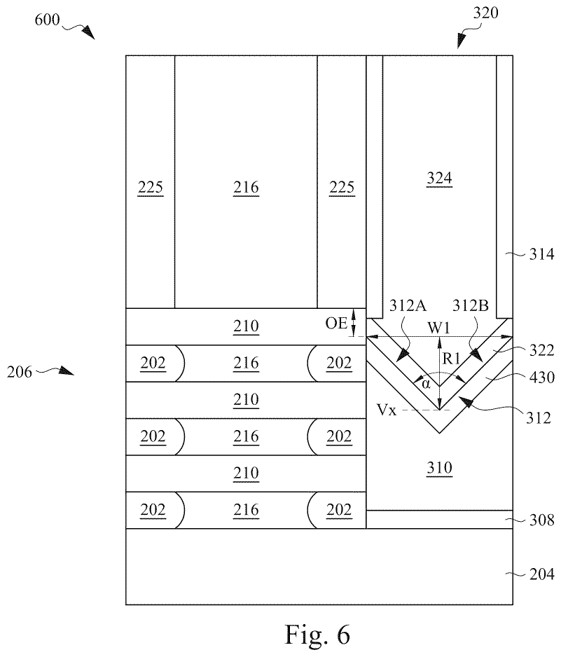

Referring to FIG. 6, illustrated therein is an exemplary semiconductor device 600 including a source/drain feature with a V-shaped profile, in accordance with some embodiments of the present disclosure. The device 600 is substantially the same as the device 500, discussed above and including the over etch height OE, however the device 600 has a different total height of the source/drain contact feature 320. As shown, the total height of the source/drain contact feature 320 of the device 600 is greater than the total height of the source/drain contact feature 320 of the device 500. Moreover, in the example shown, the top surfaces of the spacer layers 225, the gate structure 216, the contact metal layer 324 of the source/drain contact feature 320, and the dielectric layer 314 may be substantially coplanar (e.g., similar to the example of the device 200).

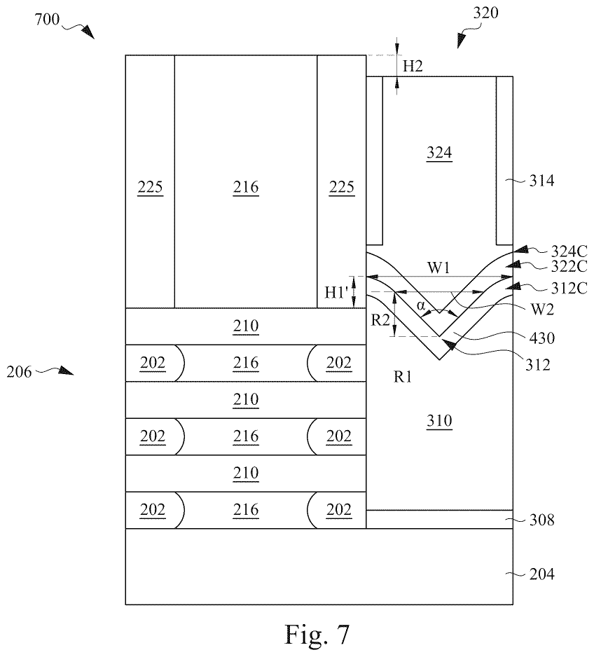

Referring to FIG. 7, illustrated therein is an exemplary semiconductor device 700 including a source/drain feature with a V-shaped profile, in accordance with some embodiments of the present disclosure. The device 500 is similar to the devices 200, 400 and includes many of the same features (identified by like reference numbers) as discussed above, thus for the sake of clarity only those features that are different in the device 700 are highlighted and discussed. In some embodiments, and with reference to the device 700, a width W2 is defined as a width of the source/drain feature 310 over which the angle alpha (α) defined between the surfaces 312A, 312B remains substantially the same. Stated another way, the width W2 is defined as the width of the source/drain feature 310 over which a shape of the V-shaped profile 312 remains substantially the same (e.g., where the surfaces 312A, 312B are substantially planar). In some embodiments, the width W2 may be in a range between about 2.31 nm-4.37 nm when the recess R2, discussed below, is equal to about 4 nm. Thus, the width W2 may be less than the width W1 of the entirety of the source/drain feature 310. In particular, in some embodiments and on opposite sides of the source/drain feature 310, the V-shaped profile 312 may have curved profile regions 312C due to curves formed in the surfaces 312A, 312B outside the boundaries of the width W2. In embodiments that include the curved profile regions 312C, a recess R2 of the V-shaped profile 312 is defined as a distance between a vertex of the V-shaped profile 312 and the plane level with the topmost portion over which the angle alpha (α) defined between the surfaces 312A, 312B is substantially the same (or over which a shape of the V-shaped profile 312 is substantially the same due to the planarity of the surfaces 312A, 312B). In some embodiments, the recess R2 may be equal to at least 4 nm. As previously noted, the recess R1 (FIG. 4) of the V-shaped profile 312 (the distance between the vertex of the V-shaped profile 312 and the plane level with the topmost portion of the source/drain feature 310) may be in a range between about 8 nm-30 nm. In some examples, the recess R1 may be referred to as the total recess of the V-shaped profile 312, and the recess R2 may be referred to as the minimum recess over which the V-shaped profile 312 has a constant profile shape. In at least some embodiments, the width W1 may be substantially equal to the width W2, meaning that in some cases, the V-shaped profile 312 has a constant profile shape over the entirety of the width of the source/drain feature 310. In some examples, in contrast to the example of FIG. 4 and due to the curved profile regions 312C, the height H1 of the source/drain feature 310 (defined as the distance between the first plane defined by a top surface of the topmost epitaxial layer 210 and the second plane, parallel to the first plane, level with the topmost portion of the source/drain feature 310) may be reduced to a height H1′. In addition, and as shown in the example of FIG. 7, the silicide layer 322 formed over the source/drain feature 310 may also include curved profile regions 322C that follow the curved profile regions 312C. Further, in some cases, the contact metal layer 324 formed over the silicide layer 322 may also include curved profile regions 324C that follow the curved profile regions 322C.

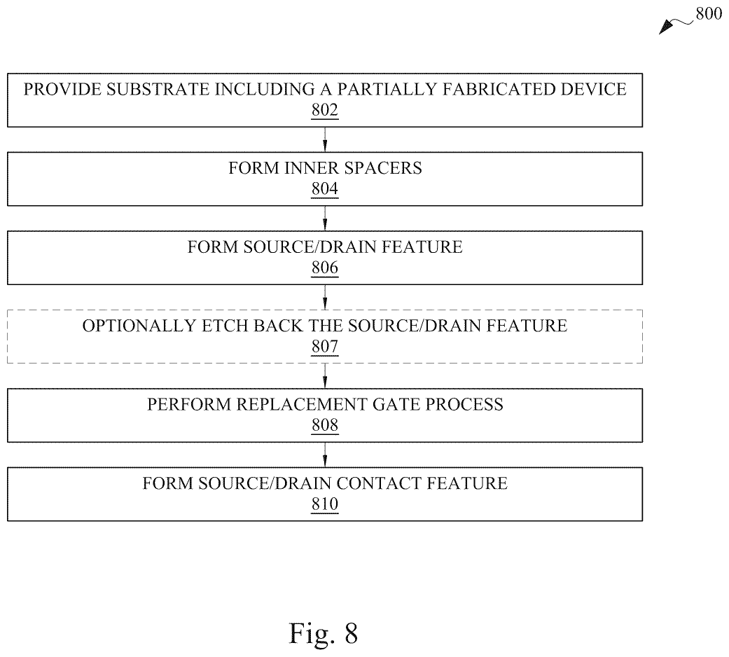

Referring now to FIG. 8, illustrated is a method 800 of forming a source/drain feature with a V-shaped profile, in accordance with some embodiments. The method 1200 is described with reference to FIGS. 1-7. Thus, one or more aspects discussed above may also apply to the method 800. It is understood that parts of the method 800 and/or any of the exemplary transistor devices discussed with reference to the method 800 may be fabricated by a well-known complementary metal-oxide-semiconductor (CMOS) technology process flow, and thus some processes are only briefly described herein. Also, additional steps may be performed before, after, and/or during the method 800. Moreover, it is noted that the process steps of the method 800, including any descriptions given with reference to the figures are merely exemplary and are not intended to be limiting beyond what is specifically recited in the claims that follow.

The method 800 begins at block 802 where a substrate including a partially fabricated device is provided. The substrate may be as described above with reference to the semiconductor device 200. In some embodiments, the partially fabricated device includes a dummy gate structure disposed over a stack of semiconductor channel layers (epitaxial layers 210) with interleaving dummy layers (SiGe). In some examples, spacer layers (e.g., such as the spacers layers 225) are formed on sidewalls of the dummy gate structure.

The method 800 proceeds to block 804 where inner spacers are formed. Initially, in some embodiments, a source/drain etch process is performed to remove portions of the semiconductor channel layers (epitaxial layers 210) and the interleaving dummy layers (SiGe) in source/drain regions of the device (e.g., adjacent to and on either side of the dummy gate structure) to form trenches which expose underlying portions of the substrate. The source/drain etch process also exposes lateral surfaces of the semiconductor channel layers (epitaxial layers 210) and the interleaving dummy layers (SiGe). After the source/drain etch process, the interleaving dummy layers (SiGe) are etched along their exposed lateral ends to form recesses within which inner spacers (e.g., such as the inner spacers 202) are formed. The inner spacers 202 may be as described above.

The method 800 then proceeds to block 806 where a source/drain feature is formed. Initially, in some embodiments, an isolation layer (e.g., such as the isolation layer 308) is formed within the trenches (e.g., formed by the source/drain etch process) of the device and over the exposed portions of the substrate. Thereafter, in some embodiments, the source/drain feature (e.g., such as the source/drain feature 310) is formed in source/drain regions adjacent to and on either side of the dummy gate structure. Further, the source/drain feature may be formed over the isolation layer and in contact with the adjacent inner spacers and the semiconductor channel layers (the epitaxial layers 310). The source/drain feature will have a substantially V-shaped profile (e.g., such as the V-shaped profile 312) along the top surface of the source/drain feature. In various embodiments, the source/drain feature may be formed as described above, be composed of one or more materials as described above, be doped with one or more of the dopant species as described above, and have one or more of the features as described above. In particular, and in various embodiments, the V-shaped profile of the source/drain feature may be formed by controlling the ratio of silane-to-dichlorosilane during the epitaxial growth of the source/drain feature (e.g., including during growth of the first layer ‘L1’ and/or the second layer ‘L2’). In some examples, the ratio of silane-to-dichlorosilane used during the epitaxial growth of the source/drain feature is between about 0 (no silane) to about 0.4. The ratio of silane-to-dichlorosilane, as also discussed above, may be controlled by using an appropriate flow rate of each of a silane precursor and a dichlorosilane precursor during epitaxial growth of the source/drain feature.

After forming the source/drain feature (block 806), the method may optionally proceed to block 807 to perform a source/drain etch back process, such as discussed above with respect to FIG. 5. Alternatively, after forming the source/drain feature and in some embodiments, the method may proceed instead to block 808. At block 808 of the method 800 a replacement gate process is performed. In some embodiments, after formation of the source/drain feature and as part of the replacement gate process, the dummy gate structure and remaining portions of the interleaving dummy layers (SiGe) are removed and replaced with a high-K/metal gate structure (e.g., such as the gate structure 216). Thus, the inner spacers may be in contact with opposing ends of portions of the high-K/metal gate structure disposed between adjacent semiconductor channel layers (the epitaxial layers 310). The inner spacers are also in contact with respective top and bottom surfaces of lateral ends of adjacent semiconductor channel layers (the epitaxial layers 310).

The method then proceeds to block 810 where a source/drain contact feature is formed. In some embodiments, a CESL and an ILD layer may initially be formed, after which a contact opening is formed that exposes the V-shaped profile of the source/drain feature. Thereafter, in some embodiments, a silicide layer (e.g., such as the silicide layer 322) is formed over the exposed source/drain feature, and then a contact metal layer (e.g., such as the contact metal layer 324) is formed oved the silicide layer. The silicide layer and the contact metal layer may be as discussed above. Moreover, in accordance with embodiments of the present disclosure, the V-shaped profile of the source/drain feature provides an increased contact area between the source/drain feature and the source/drain contact feature, thereby lowering the source/drain contact resistance and boosting performance of the device.

With respect to the description provided herein, disclosed are methods and structures for forming a source/drain feature having a V-shaped profile to effectively reduce source/drain contact resistance. In contrast to at least some existing implementations, embodiments of the present disclosure provide for an increased contact area between the source/drain feature and the contact metal layer by providing a substantially V-shaped profile disposed along the top surface of the source/drain feature. In various embodiments, the V-shaped profile of the source/drain feature may be formed by control of the epitaxial growth process used to form the source/drain feature. For example, in some cases, silicon precursors including silane (SiH₄) and dichlorosilane (SiH₂Cl₂) may be used during the epitaxial growth of the source/drain feature. In particular, and in various embodiments, by controlling the ratio of silane-to-dichlorosilane during the epitaxial growth process, the V-shaped profile of the source/drain feature may be formed. In some examples, the ratio of silane-to-dichlorosilane used for the epitaxial growth process is between about 0 (no silane) to about 0.4.

Thus, one of the embodiments of the present disclosure described a semiconductor device including a plurality of stacked nanostructures disposed over a substrate, a source/drain feature adjacent to the plurality of stacked nanostructures, and a source/drain contact feature disposed over the source/drain feature. In some embodiments, the source/drain feature has a substantially V-shaped profile along a top surface of the source/drain feature.

In another of the embodiments, discussed is a semiconductor device including a plurality of channel layers stacked over a substrate, a gate structure including a first portion disposed over the plurality of channel layers and a second portion disposed between adjacent channel layers of the plurality of channel layers, and a source/drain feature adjacent to the gate structure. In some embodiments, the source/drain feature has a top surface that defines a V-shaped profile.

In yet another of the embodiments, discussed is a method including providing a substrate having a stack of semiconductor channel layers and a gate structure disposed over the stack of semiconductor channel layers. In some embodiments, the method further includes forming a source/drain feature in a source/drain region adjacent to the gate structure. In some embodiments, the method further includes forming a source/drain contact feature over the source/drain feature. In some embodiments, the forming the source/drain feature includes selecting a flow rate for each of a silane precursor and a dichlorosilane precursor to provide a ratio of silane-to-dichlorosilane that forms a V-shaped profile along a top surface of the source/drain feature during epitaxial growth of the source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of stacked nanostructures disposed over a substrate;
a source/drain feature adjacent to the plurality of stacked nanostructures; and
a source/drain contact feature disposed over the source/drain feature;
wherein the source/drain feature has a substantially V-shaped profile along a top surface of the source/drain feature.

2. The semiconductor device of claim 1, wherein an angle alpha (α) is defined between opposing surfaces of the V-shaped profile disposed along the top surface of the source/drain feature.

3. The semiconductor device of claim 1, wherein the angle alpha (α) is in a range between about 60 degrees and 95 degrees.

4. The semiconductor device of claim 1, wherein the V-shaped profile has a width in a range between about 8 nm-25 nm.

5. The semiconductor device of claim 1, wherein a first plane level with a topmost portion of the source/drain feature extends a distance above a second plane defined by a top surface of a topmost nanostructure of the plurality of stacked nanostructures.

6. The semiconductor device of claim 5, wherein the distance is in a range between about 0 nm-15 nm.

7. The semiconductor device of claim 1, wherein the V-shaped profile has a recess defined as a distance between a vertex of the V-shaped profile and a plane level with a topmost portion of the source/drain feature.

8. The semiconductor device of claim 7, wherein the recess is in a range between about 8 nm-30 nm.

9. The semiconductor device of claim 1, further comprising:
a silicide layer in contact with the V-shaped profile of the source/drain feature; and
a contact metal layer disposed over the silicide layer.

10. The semiconductor device of claim 1, wherein the source/drain feature further includes a dopant species rich layer formed within a top portion of the source/drain feature along the V-shaped profile.

11. The semiconductor device of claim 10, further comprising:
a silicide layer in contact with the dopant species rich layer of the source/drain feature; and
a contact metal layer disposed over the silicide layer.

12. A semiconductor device, comprising:
a plurality of channel layers stacked over a substrate;
a gate structure including a first portion disposed over the plurality of channel layers and a second portion disposed between adjacent channel layers of the plurality of channel layers; and
a source/drain feature adjacent to the gate structure;
wherein the source/drain feature has a top surface that defines a V-shaped profile.

13. The semiconductor device of claim 12, wherein a topmost portion of the source/drain feature extends above a first plane defined by a top surface of a topmost channel layer of the plurality of channel layers, and wherein a second plane that is level with a vertex of the V-shaped profile is disposed below the first plane.

14. The semiconductor device of claim 12, wherein a topmost portion of the source/drain feature extends above a first plane defined by a top surface of a topmost channel layer of the plurality of channel layers, and wherein a second plane that is level with a vertex of the V-shaped profile is disposed below a third plane defined by a bottom surface of the topmost channel layer of the plurality of channel layers.

15. The semiconductor device of claim 12, wherein a topmost portion of the source/drain feature is level with a first plane defined by a top surface of a topmost channel layer of the plurality of channel layers.

16. The semiconductor device of claim 12, wherein a topmost portion of the source/drain feature is level with a first plane defined by a bottom surface of a topmost channel layer of the plurality of channel layers, and wherein a second plane that is level with a vertex of the V-shaped profile is disposed below a third plane defined by a top surface of a middle channel layer of the plurality of channel layers.

17. The semiconductor device of claim 12, wherein a topmost portion of the source/drain feature is disposed between a first plane defined by a top surface of a middle channel layer of the plurality of channel layers and a second plane defined by a bottom surface of a topmost channel layer of the plurality of channel layers, and wherein a third plane that is level with a vertex of the V-shaped profile is disposed below a fourth plane defined by a bottom surface of the middle channel layer of the plurality of channel layers.

18. The semiconductor device of claim 12, wherein the V-shaped profile includes curved profile regions on opposite sides of the source/drain feature.

19. A method, comprising:
providing a substrate including a stack of semiconductor channel layers and a gate structure disposed over the stack of semiconductor channel layers;
forming a source/drain feature in a source/drain region adjacent to the gate structure; and
forming a source/drain contact feature over the source/drain feature;
wherein the forming the source/drain feature includes selecting a flow rate for each of a silane precursor and a dichlorosilane precursor to provide a ratio of silane-to-dichlorosilane that forms a V-shaped profile along a top surface of the source/drain feature during epitaxial growth of the source/drain feature.

20. The method of claim 19, further comprising:
after forming the source/drain feature and prior to forming the source/drain contact feature, performing a source/drain etch back process without impacting a shape of the V-shaped profile.
